(19) United States
(12) Patent Application Publication
(10) Pub. No.: US 2020/0181403 A1
(43) Pub. Date: Jun. 11, 2020

(54) POLY(PHENYLENE ETHER) RESIN COMPOSITION, AND PREPREG, METAL-CLAD LAMINATE, AND WIRING BOARD EACH OBTAINED USING SAME

(71) Applicant: PANASONIC INTELLECTUAL PROPERTY MANAGEMENT CO., LTD., Osaka (JP)

(72) Inventors: Fumito SUZUKI, Fukushima (JP); Hiroaki UMEHARA, Fukushima (JP); Jun YASUMOTO, Osaka (JP); Hiroharu INOUE, Osaka (JP)

(73) Assignee: PANASONIC INTELLECTUAL PROPERTY MANAGEMENT CO., LTD., Osaka (JP)

(21) Appl. No.: 16/641,928

(22) PCT Filed: Jun. 29, 2018
(86) PCT No.: PCT/JP2018/024819

§ 371 Date: Feb. 25, 2020

(30) Foreign Application Priority Data
Aug. 31, 2017 (JP) 2017-166462

(51) Int. Cl. C08L 71/12; C08K 5/5399; C08J 5/24; B32B 15/08; H05K 1/03

(52) U.S. Cl. CPC C08L 71/126; C08K 5/5399; C08J 5/24; C08L 2312/00; H05K 1/0353; C08L 2201/02; B32B 15/08

(57) ABSTRACT

The present application relates to a polyphenylene ether resin composition containing (A) a modified polyphenylene ether compound having a terminal modified with a substituent having an unsaturated carbon-carbon double bond, (B) a crosslinking curing agent having an unsaturated carbon-carbon double bond in the molecule, and (C) a flame retardant. The flame retardant (C) contains at least a modified cyclic phenoxy phosphazene compound represented by formula (I).

### TECHNICAL FIELD

The present invention relates to a polyphenylene ether resin composition, and a prepreg, a metal-clad laminate, and a wiring board each obtained by using the polyphenylene ether resin composition.

### BACKGROUND ART

In recent years, mounting techniques for, for example, achieving high integration of mounted semiconductor devices, high wiring density, and multilayering are rapidly developing with increasing amount of information processing in various electronic devices. Board materials for forming a base material of a printed wiring board used in various electronic devices need to have low permittivity and low dissipation factor in order to increase signal transmission speed and reduce signal transmission loss.

Polyphenylene ethers (PPEs) are known to have good dielectric characteristics, such as permittivity and dissipation factor and also have good dielectric characteristics, such as permittivity and dissipation factor, in a high frequency band (high frequency region) from MHz band to GHz band.

Polyphenylene ethers thus have been studied, for example, for use as forming materials for high frequency. More specifically, polyphenylene ethers are preferably used as, for example, board materials for forming a base material of a printed wiring board in an electronic device using a high frequency band.

Materials used as forming materials, such as board materials, need to have not only good dielectric characteristics but also high flame retardancy. In terms of this point, a typical resin composition used as a forming material, such as a board material, often contains a halogen-containing compound, for example, a halogenated flame retardant such as a brominated flame retardant, or a halogen-containing epoxy resin such as tetrabromobisphenol A epoxy resin.

However, a falling object made of a resin composition containing such a halogen-containing compound will contain a halogen and may generate a hazardous substance, such as a hydrogen halide, during combustion. Such a hazardous substance may have an adverse effect on human bodies and natural environments. In light of this background, forming materials such as board materials need to contain no halogen, that is, need to be free of halogens.

Examples of such halogen-free resin compositions include the resin composition described in Patent Literature 1.

The resin composition described in Patent Literature 1 contains, as flame retardants, a phosphorus compound that is compatible with a resin component and a phosphorus compound that is incompatible with the resin component. In particular, a phosphazene compound is contained to exhibit high flame retardancy. However, the polyphenylene ether resin composition described in Patent Literature 1 is found to have slightly poor low dielectric characteristics (particularly Df) although having an effect on flame retardancy. To satisfy a high demand for low dielectric characteristics in these days, there is a need for a flame retardant that exhibits better dielectric characteristics.

Since the phosphazene compound which is a flame retardant described in Patent Literature 1 normally tends to be compatible with resin, the phosphazene compound advantageously provides high resin flow and improves the formability of the resin composition. However, the larger the amount of the phosphazene compound, the lower the Tg of the resin composition.

In light of such circumstances, the present invention is directed to a resin composition having good dielectric characteristics and high flame retardancy and heat resistance and also having high formability and high Tg. The present invention is also directed to a prepreg, a metal-clad laminate, and a wiring board each obtained by using the resin composition.

### CITATION LIST

### Patent Literature

### Patent Literature 1: JP 2015-86330 A

### SUMMARY OF INVENTION

A polyphenylene ether resin composition according to an aspect of the present invention includes (A) a modified polyphenylene ether compound having a terminal modified with a substituent having an unsaturated carbon-carbon double bond, (B) a crosslinking curing agent having an unsaturated carbon-carbon double bond in the molecule, and (C) a flame retardant. The flame retardant (C) contains at least a modified cyclic phenoxy phosphazene compound represented by formula (I) below.

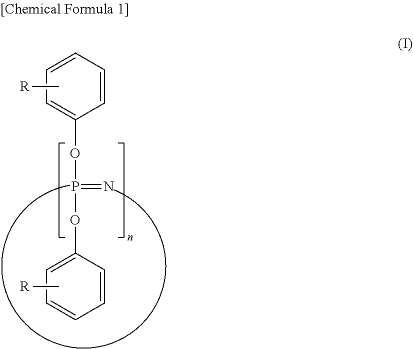

In the above-mentioned (I), n represents an integer from 3 to 25. At least one of R's represents a C1 to C10 aliphatic alkyl group or cyano group, and the remaining R's represent a hydrogen atom.

### BRIEF DESCRIPTION OF DRAWINGS

FIG. 1 is a schematic cross-sectional view illustrating the structure of a prepreg according to an embodiment of the present invention.

FIG. 2 is a schematic cross-sectional view illustrating the structure of a metal-clad laminate according to an embodiment of the present invention.

FIG. 3 is a schematic cross-sectional view illustrating the structure of a wiring board according to an embodiment of the present invention.

### DESCRIPTION OF EMBODIMENTS

A polyphenylene ether resin composition according to an embodiment of the present invention includes (A) a modified polyphenylene ether compound having a terminal modified with a substituent having an unsaturated carbon-carbon double bond, (B) a crosslinking curing agent having an unsaturated carbon-carbon double bond in the molecule, and (C) a flame retardant. The flame retardant (C) contains at least a modified cyclic phenoxy phosphazene compound represented by formula (1) below.

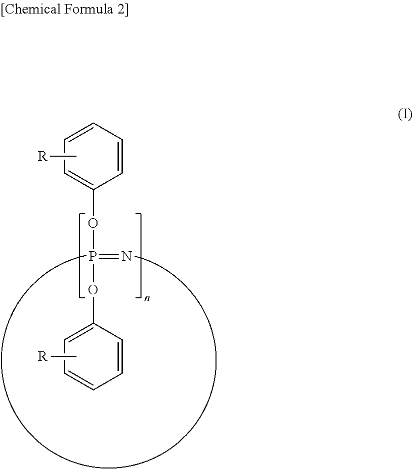

In the above-mentioned formula (I), n represents an integer from 3 to 25. At least one of R's represents a C1 to C10 aliphatic alkyl group or cyano group, and the remaining R's represent a hydrogen atom.

The polyphenylene ether resin composition containing the modified cyclic phenoxy phosphazene compound represented by the above formula as a cyclic phosphazene compound serving as a flame retardant can exhibit high flame retardancy and heat resistance without degrading low dielectric characteristics (Df). The resin composition according to this embodiment further has high resin flow and thus achieves high formability and high Tg at the same time.

In other words, the present invention can provide a resin composition having good dielectric characteristics and high flame retardancy and heat resistance and also having high formability and high Tg. The present invention can also provide a prepreg, a metal-clad laminate, and a wiring board each obtained by using the resin composition.

The components of the resin composition according to this embodiment will be specifically described below.

The modified polyphenylene ether used in this embodiment is not limited and may be any modified polyphenylene ether that has a terminal modified with a substituent having an unsaturated carbon-carbon double bond.

The substituent having an unsaturated carbon-carbon double bond is not limited. Examples of the substituent include substituents represented by formula (1) below.

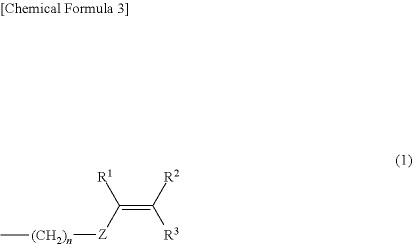

In formula (1), n represents 0 to 10. Z represents an allylene group. R¹ to R³ are independent of each other. In other words, R¹ to R³ may be the same groups or different groups. R¹ to R³ represent a hydrogen atom or an alkyl group.

When n is 0 in formula (1), Z is directly bonded to the terminal of polyphenylene ether.

The allylene group is not limited. Specific examples of the allylene group include monocyclic aromatic groups such as a phenylene group, and polycyclic aromatic groups in which an aromatic ring is not a monocyclic ring but a polycyclic ring, such as naphthalene ring. Examples of the allylene group further include derivatives in which a hydrogen atom bonded to an aromatic ring is substituted with a functional group, such as an alkenyl group, an alkynyl group, a formyl group, an alkylcarbonyl group, an alkenylcarbonyl group, or an alkynylcarbonyl group. The alkyl group is preferably but not necessarily, for example, a C1 to C18 alkyl group, more preferably a C1 to C10 alkyl group. Specific examples include a methyl group, an ethyl group, a propyl group, a hexyl group, and a decyl group.

Specific examples of the substituent include vinylbenzyl groups (ethenylbenzyl groups), such as a p-ethenylbenzyl group and an m-ethenylbenzyl group; a vinylphenyl group; an acrylate group; and a methacrylate group.

Preferred specific examples of the substituent represented by formula (1) above include functional groups including a vinylbenzyl group. Specifically, the substituent represented by formula (1) above is, for example, at least one substituent selected from formula (2) and formula (3) below.

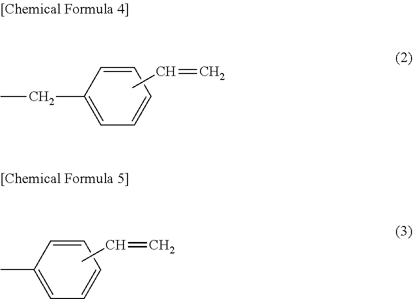

Examples of other substituents that have an unsaturated carbon-carbon double bond and with which the terminal of the modified polyphenylene ether used in this embodiment is modified include (meth)acrylate groups. Examples of (meth)acrylate groups include groups represented by formula (4) below.

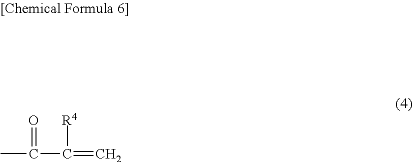

In formula (4), R⁴ represents a hydrogen atom or an alkyl group. The alkyl group is preferably but not necessarily, for example, a C1 to C18 alkyl group, more preferably a C1 to C10 alkyl group. Specific examples of the alkyl group include a methyl group, an ethyl group, a propyl group, a hexyl group, and a decyl group.

The modified polyphenylene ether according to this embodiment has a polyphenylene ether chain in the molecule and preferably includes, for example, a repeating unit represented by formula (5) in the molecule.

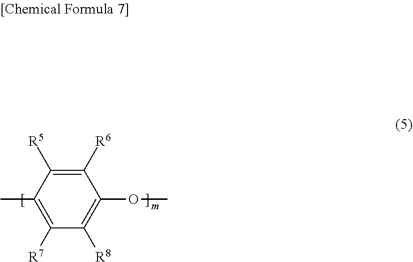

In formula (5), m represents 1 to 50. R⁵ to R⁸ are independent of each other. In other words, R⁵ to R⁸ may be the same groups or different groups. R⁵ to R⁸ represent a hydrogen atom, an alkyl group, an alkenyl group, an alkynyl group, a formyl group, an alkylcarbonyl group, an alkenylcarbonyl group, or an alkynylcarbonyl group. Among these groups, a hydrogen atom and an alkyl group are preferred.

Specific examples of the functional groups exemplified as R⁵ to R⁸ include the following groups.

The alkyl group is preferably but not necessarily, for example, a C1 to C18 alkyl group, more preferably a C1 to C10 alkyl group. Specific examples of the alkyl group include a methyl group, an ethyl group, a propyl group, a hexyl group, and a decyl group.

The alkenyl group is preferably but not necessarily, for example, a C2 to C18 alkenyl group, more preferably a C2 to C10 alkenyl group. Specific examples of the alkenyl group include a vinyl group, an allyl group, and a 3-butenyl group.

The alkynyl group is preferably but not necessarily, for example, a C2 to C18 alkynyl group, more preferably a C2 to C10 alkynyl group. Specific examples of the alkynyl group include an ethynyl group and a prop-2-yn-1-yl group (propargyl group).

The alkylcarbonyl group is not limited and may be any carbonyl group that is substituted with an alkyl group. The alkylcarbonyl group is preferably, for example, a C2 to C18 alkylcarbonyl group, more preferably a C2 to C10 alkylcarbonyl group. Specific examples of the alkylcarbonyl group include an acetyl group, a propionyl group, a butyryl group, an isobutyryl group, a pivaloyl group, a hexanoyl group, an octanoyl group, and a cyclohexylcarbonyl group.

The alkenylcarbonyl group is not limited and may be any carbonyl group that is substituted with an alkenyl group. The alkenylcarbonyl group is preferably, for example, a C3 to C18 alkenylcarbonyl group, more preferably a C3 to C10 alkenylcarbonyl group. Specific examples of the alkenylcarbonyl group include an acryloyl group, a methacryloyl group, and a crotonoyl group.

The alkynylcarbonyl group is not limited and may be any carbonyl group that is substituted with an alkynyl group. The alkynylcarbonyl group is preferably, for example, a C3 to C18 alkynylcarbonyl group, more preferably a C3 to C10 alkynylcarbonyl group. Specific examples of the alkynylcarbonyl group include a propioloyl group.

The weight-average molecular weight (Mw) of the modified polyphenylene ether compound used in this embodiment is not limited. Specifically, the weight-average molecular weight is preferably from 500 to 5000, more preferably from 800 to 4000, still more preferably from 1000 to 3000. The weight-average molecular weight is any value measured by a common molecular weight measurement method and is specifically, for example, a value measured by using gel permeation chromatography (GPC). When the modified polyphenylene ether compound has the repeating unit represented by formula (2) in the molecule, m is preferably a numerical value such that the modified polyphenylene ether compound has a weight-average molecular weight in this range. Specifically, m is preferably from 1 to 50.

The modified polyphenylene ether compound having a weight-average molecular weight in this range has good dielectric characteristics attributed to the polyphenylene ether and not only provides a cured product having high heat resistance but also achieves good formability. This may be based on the following reasons. A typical polyphenylene ether having a weight-average molecular weight in such a range has a relatively low molecular weight and thus tends to provide a cured product having low heat resistance. In terms of this point, the modified polyphenylene ether compound according to this embodiment has an unsaturated double bond in its terminal, which may provide a cured product having sufficiently high heat resistance. Since a modified polyphenylene ether compound having a weight-average molecular weight in such a range has a relatively low molecular weight, the modified polyphenylene ether compound may achieve good formability. Therefore, such a modified polyphenylene ether compound not only provides a cured product having high heat resistance but also achieves good formability.

In the modified polyphenylene ether compound used in this embodiment, the average number of the substituents in the molecule terminal (the number of terminal functional groups) per modified polyphenylene ether molecule is not limited. Specifically, the number of terminal functional groups is preferably from 1 to 5, more preferably from 1 to 3, still more preferably from 1.5 to 3. If the number of terminal functional groups is too small, the cured product is unlikely to have sufficient heat resistance. If the number of terminal functional groups is too large, the reactivity is too high, which may cause problems of, for example, low storage stability of the resin composition or low flowability of the resin composition. In other words, if such a modified polyphenylene ether is used, insufficient flowability and the like may cause, for example, a formability problem in which generation of forming defects, such as void formation during multilayer forming, makes it difficult to provide a printed circuit board having high reliability.

The number of terminal functional groups in the modified polyphenylene ether compound is, for example, a numerical value that expresses the average number of the substituents per molecule for all modified polyphenylene ether compounds present in one mole of the modified polyphenylene ether compound. The number of terminal functional groups can be measured by, for example, determining the number of hydroxyl groups remaining in the obtained modified polyphenylene ether compound and calculating the decrement from the number of hydroxyl groups in polyphenylene ether before modification. The decrement from the number of hydroxyl groups in the polyphenylene ether before modification corresponds to the number of terminal functional groups. The number of hydroxyl groups remaining in the modified polyphenylene ether compound can be obtained by adding, to a solution of the modified polyphenylene ether compound, a quaternary ammonium salt (tetraethylammonium hydroxide) which associates with hydroxyl groups and measuring the UV absorbance of this mixed solution.

The intrinsic viscosity of the modified polyphenylene ether compound used in this embodiment is not limited. Specifically, the intrinsic viscosity is from 0.03 to 0.12 dl/g, preferably from 0.04 to 0.11 dl/g, and more preferably from 0.06 to 0.095 dl/g. If the intrinsic viscosity is too low, the molecular weight tends to be low, and it tends to be difficult to obtain low dielectric properties, such as low permittivity and low dissipation factor. If the intrinsic viscosity is too high, sufficient flowability is not obtained due to high viscosity, and the cured product tends to have low formability. Therefore, the modified polyphenylene ether compound having an intrinsic viscosity in the above range can provide a cured product having high heat resistance and achieve good formability.

The term “intrinsic viscosity” as used herein refers to an intrinsic viscosity measured in methylene chloride at 25° C. More specifically, the intrinsic viscosity is, for example, a value obtained by measuring, for example, 0.18 g/45 m of methylene chloride solution (solution temperature 25° C.) with a viscometer. The viscometer is, for example, AVS 500 Visco System available from Schott Instruments.

The method for synthesizing the modified polyphenylene ether compound used in this embodiment is not limited as long as a modified polyphenylene ether compound having a terminal modified with a substituent having an unsaturated carbon-carbon double bond can be synthesized.

Specific examples of the synthesis method include a method of causing polyphenylene ether to react with a compound in which a substituent having an unsaturated carbon-carbon double bond is bonded to a halogen atom.

Examples of the compound in which a substituent having an unsaturated carbon-carbon double bond is bonded to a halogen atom include compounds represented by formula (6).

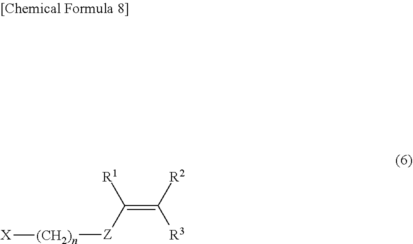

In formula (6), n, Z, and R¹ to R³ are the same as n, Z, and R¹ to R³ in formula (1). Specifically, n represents 0 to 10. Z represents an allylene group. R¹ to R³ are independent of each other. In other words, R¹ to R³ may be the same groups or different groups. R¹ to R³ represent a hydrogen atom or an alkyl group. X represents a halogen atom, and specific examples of the halogen atom include a chlorine atom, a bromine atom, an iodine atom, a fluorine atom. Among these, a chlorine atom is preferred.

The compound represented by formula (6) may be one of the above exemplary compounds or a combination of two or more of the above exemplary compounds.

Examples of the compound in which a substituent having an unsaturated carbon-carbon double bond is bonded to a halogen atom include p-chloromethylstyrene and m-chloromethylstyrene.

The polyphenylene ether, serving as a raw material, is not limited as long as a particular modified polyphenylene ether can be finally synthesized. Specific examples of the polyphenylene ether include those composed mainly of a polyphenylene ether made up of 2,6-dimethylphenol and at least one of a bifunctional phenol and a trifunctional phenol, or mainly of a polyphenylene ether, such as poly(2,6-dimethyl-1,4-phenylene oxide). The bifunctional phenol is a phenolic compound having two phenolic hydroxyl groups in the molecule. Examples of the bifunctional phenol include tetramethyl bisphenol A. The trifunctional phenol is a phenolic compound having three phenolic hydroxyl groups in the molecule. Specific examples of such a polyphenylene ether include polyphenylene ethers having the structure represented by formula (7) below or formula (9) below.

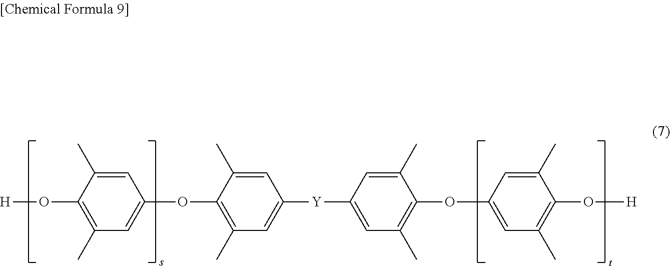

In formula (7), s and t are, for example, preferably such that the sum of s and t is from 1 to 30. Furthermore, s is preferably from 0 to 20, and t is preferably from 0 to 20. That is, s preferably represents from 0 to 20, t preferably represents from 0 to 20, and the sum of s and t is preferably from 1 to 30. Y represents a linear, branched or cyclic hydrocarbon group. Examples of the group represented by Y include groups represented by formula (8) below.

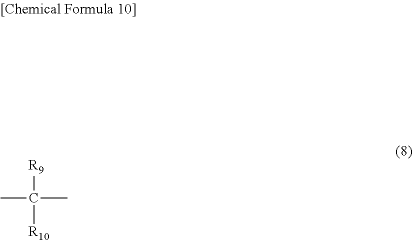

In formula (8) above, R⁹ to R¹⁰ each independently represent a hydrogen atom or an alkyl group. Examples of the alkyl group include a methyl group. Examples of the group represented by formula (8) include a methylene group, a methyl methylene group, and a dimethyl methylene group.

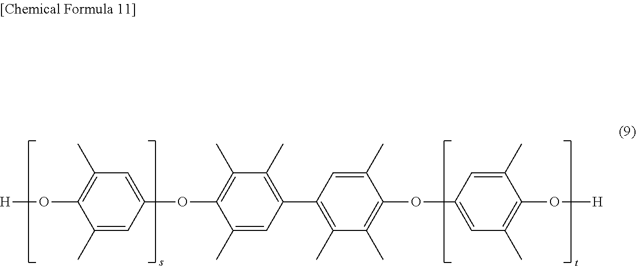

In formula (9), s and t are the same as s and t in formula (7).

The modified polyphenylene ether compound is preferably a polyphenylene ether having the structure represented by formula (7) or formula (9) whose terminal is modified with a substituent having an unsaturated carbon-carbon double bond as described above. The modified polyphenylene ether compound is, for example, the polyphenylene ether represented by formula (7) or formula (9) above whose terminal has the group represented by formula (1) or formula (4). Specific examples of the modified polyphenylene ether compound include modified polyphenylene ether compounds represented by formula (10) to formula (13) below.

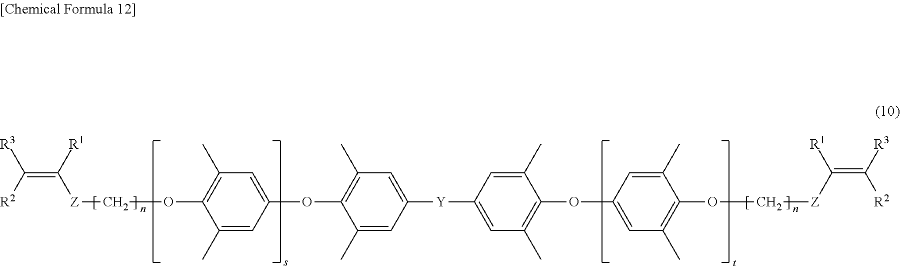

In formula (10), s and t are the same as s and t in formula (7), and Y is the same as Y in formula (7). In formula (10), R¹ to R³ are the same as R¹ to R³ in formula (1) above, Z is the same as Z in formula (1) above, and n is the same as n in formula (1) above.

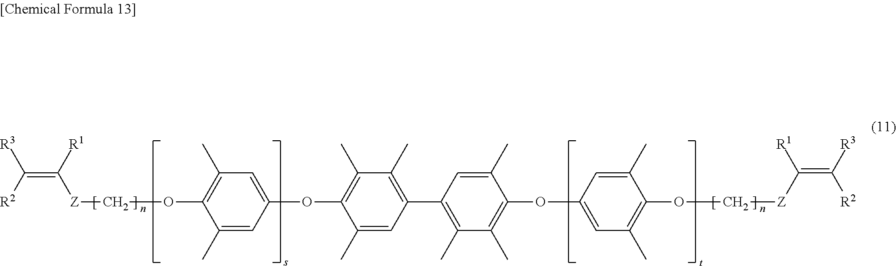

In formula (11), s and t are the same as s and t in formula (7). In formula (11), R¹ to R³ are the same as R1 to R3 in formula (1) above, Z is the same as Z in formula (1) above, and n is the same as n in formula (1) above.

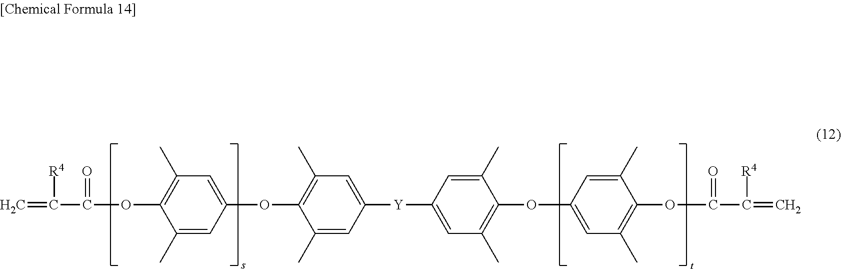

In formula (12), s and t are the same as s and t in formula (7), and Y is the same as Y in formula (7). In formula (12), R⁴ is the same as R⁴ in formula (4) above.

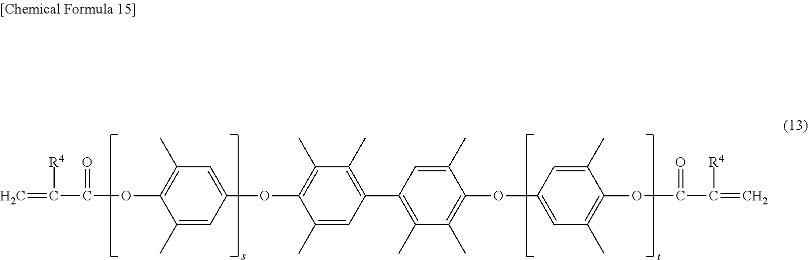

In formula (13), s and t are the same as s and t in formula (7). In formula (13), R⁴ is the same as R⁴ in formula (4) above.

Examples of the method for synthesizing the modified polyphenylene ether compound include the method described above. In an exemplary method, specifically, the polyphenylene ether as described above and the compound represented by formula (6) are dissolved in a solvent, and the mixture is stirred. This allows the polyphenylene ether to react with the compound represented by formula (6) to produce a modified polyphenylene ether used in this embodiment.

This reaction is preferably performed in the presence of an alkali metal hydroxide. This may allow this reaction to proceed favorably. This may be because the alkali metal hydroxide functions as a dehydrohalogenation agent, specifically functions as a dehydrochlorination agent. Specifically, the alkali metal hydroxide may remove a hydrogen halide from the phenol group of the polyphenylene ether and the compound represented by formula (6), and the substituent represented by formula (1) instead of a hydrogen atom in the phenol group of the polyphenylene ether may thus be bonded to the oxygen atom of the phenol group.

The alkali metal hydroxide is not limited and may be any alkali metal hydroxide that functions as a dehalogenation agent. Examples of the alkali metal hydroxide include sodium hydroxide. The alkali metal hydroxide is normally used in the form of aqueous solution, specifically in the form of aqueous solution of sodium hydroxide.

The reaction conditions, such as reaction time and reaction temperature, which depend on the compound represented by formula (6) and the like, are not limited and may be any reaction conditions under which the above reaction proceeds favorably. Specifically, the reaction temperature is preferably from room temperature to 100° C., more preferably from 30° C. to 100° C. The reaction time is preferably from 0.5 to 20 hours, more preferably from 0.5 to 10 hours.

The solvent used in the reaction is not limited and may be any solvent in which the polyphenylene ether and the compound represented by formula (6) are soluble and that does not inhibit the reaction between the polyphenylene ether and the compound represented by formula (6). Specific examples of the solvent include toluene.

The above reaction is preferably performed in the presence of not only an alkali metal hydroxide but also a phase-transfer catalyst. In other words, the above reaction is preferably performed in the presence of an alkali metal hydroxide and a phase-transfer catalyst. This may allow the above reaction to proceed more favorably. This may be based on the following reasons. The phase-transfer catalyst has a function of incorporating an alkali metal hydroxide. The phase-transfer catalyst is soluble in both a polar solvent phase, such as aqueous phase, and a non-polar solvent phase, such as organic solvent phase and can transfer between these phases. Specifically, when an aqueous solution of sodium hydroxide is used as an alkali metal hydroxide and an organic solvent, such as toluene, incompatible with water is used as a solvent, dropwise addition of the aqueous solution of sodium hydroxide to the solvent subjected to the reaction may result in separation of the solvent from the aqueous solution of sodium hydroxide. Thus, sodium hydroxide is unlikely to transfer to the solvent. Accordingly, the aqueous solution of sodium hydroxide added as an alkali metal hydroxide is unlikely to contribute to reaction acceleration. However, the reaction in the presence of an alkali metal hydroxide and a phase-transfer catalyst may cause the alkali metal hydroxide to transfer to the solvent, with the alkali metal hydroxide incorporated in the phase-transfer catalyst. Thus, the aqueous solution of sodium hydroxide may tend to contribute to reaction acceleration. Therefore, when the reaction is performed in the presence of an alkali metal hydroxide and a phase-transfer catalyst, the above reaction may proceed favorably.

Examples of the phase-transfer catalyst include, but are not limited to, quaternary ammonium salts, such as tetra-n-butylammonium bromide.

The resin composition according to this embodiment preferably contains, as a modified polyphenylene ether, the modified polyphenylene ether produced as described above.

Next, the component (B) used in this embodiment, that is, a crosslinking curing agent, will be described. The crosslinking curing agent used in this embodiment is not limited and may be any crosslinking curing agent that has an unsaturated carbon-carbon double bond in the molecule. In other words, the crosslinking curing agent reacts with the modified polyphenylene ether compound to form cross-linkages, thus curing the modified polyphenylene ether compound. The crosslinking curing agent is preferably a compound having two or more unsaturated carbon-carbon double bonds in the molecule.

The weight-average molecular weight of the crosslinking curing agent used in this embodiment is preferably from 100 to 5000, more preferably from 100 to 4000, still more preferably from 100 to 3000. If the weight-average molecular weight of the crosslinking curing agent is too low, the crosslinking curing agent may readily volatilize from the component system of the resin composition. If the weight-average molecular weight of the crosslinking curing agent is too high, the viscosity of varnish containing the resin composition and the melt viscosity during heat forming may be too high. When the crosslinking curing agent has a weight-average molecular weight in such a range, the resin composition provides a cured product having high heat resistance. This may be because the crosslinking curing agent can favorably form cross-linkages through the reaction with the modified polyphenylene ether compound. The weight-average molecular weight is any value measured by a common molecular weight measurement method and is specifically, for example, a value measured by using gel permeation chromatography (GPC).

Regarding the crosslinking curing agent used in this embodiment, the average number of unsaturated carbon-carbon double bonds (the number of terminal double bonds) per crosslinking curing agent molecule, which depends on the weight-average molecular weight of the crosslinking curing agent, is preferably, for example, from 1 to 20, more preferably from 2 to 18. If the number of terminal double bonds is too small, the cured product is unlikely to have sufficient heat resistance. If the number of terminal double bonds is too large, the reactivity is too high, which may cause problems of, for example, low storage stability of the resin composition or low flowability of the resin composition.

In further consideration of the weight-average molecular weight of the crosslinking curing agent, the number of terminal double bonds in the crosslinking curing agent is preferably from 1 to 4 when the crosslinking curing agent has a weight-average molecular weight of less than 500 (e.g., 100 or more and less than 500). The number of terminal double bonds in the crosslinking curing agent is preferably from 3 to 20 when the crosslinking curing agent has a weight-average molecular weight of 500 or more (e.g., 500 or more and 5000 or less). If the number of terminal double bonds is smaller than the lower limit of the above range in each case, the crosslinking curing agent has low reactivity, and the cured product of the resin composition has low crosslink density. As a result, the heat resistance and the Tg may not be high enough. If the number of terminal double bonds is larger than the upper limit of the above range, the resin composition may tend to form a gel.

The number of terminal double bonds is found from the specification of a crosslinking curing agent product used. Specifically, the number of terminal double bonds here is, for example, the numerical value that expresses the average number of terminal double bonds per molecule for all crosslinking curing agents present in one mole of the crosslinking curing agent.

Specific examples of the crosslinking curing agent used in this embodiment include trialkenyl isocyanurate compounds, such as triallyl isocyanurate (TAIC); polyfunctional methacrylate compounds having two or more methacrylic groups in the molecule; polyfunctional acrylate compounds having two or more acrylic groups in the molecule; vinyl compounds (polyfunctional vinyl compounds) having two or more vinyl groups in the molecule, such as polybutadiene; and vinylbenzyl compounds having a vinylbenzyl group in the molecule, such as styrene and divinylbenzene. Among them, crosslinking curing agents having two or more carbon-carbon double bonds in the molecule are preferred. Specific examples include trialkenyl isocyanurate compounds, polyfunctional acrylate compounds, polyfunctional methacrylate compounds, polyfunctional vinyl compounds, and divinylbenzene compounds. When these crosslinking curing agents are used, the curing reaction may favorably form cross-linkages, and the cured product of the resin composition according to this embodiment has high heat resistance. The crosslinking curing agent may be one of the above exemplary crosslinking curing agents or a combination of two or more of the above exemplary crosslinking curing agents. The crosslinking curing agent may be a combination of a compound having two or more unsaturated carbon-carbon double bonds in the molecule and a compound having one unsaturated carbon-carbon double bond in the molecule. Specific examples of the compound having one unsaturated carbon-carbon double bond in the molecule include a compound (monovinyl compound) having one vinyl group in the molecule.

The amount of the modified polyphenylene ether compound is preferably from 30 to 90 parts by mass, more preferably from 50 to 90 parts by mass, per 100 parts by mass of the total of the modified polyphenylene ether compound and the crosslinking curing agent. The amount of the crosslinking curing agent is preferably from 10 to 70 parts by mass, more preferably from 10 to 50 parts by mass, per 100 parts by mass of the total of the modified polyphenylene ether compound and the crosslinking curing agent. In other words, the content ratio of the modified polyphenylene ether compound to the crosslinking curing agent in terms of mass ratio is preferably from 90:10 to 30:70, more preferably from 90:10 to 50:50. When the amount of each of the modified polyphenylene ether compound and the crosslinking curing agent satisfies the above range, the resin composition provides a cured product with high heat resistance and flame retardancy. This may be because the curing reaction between the modified polyphenylene ether compound and the crosslinking curing agent proceeds favorably.

Next, the flame retardant (C) will be described. The flame retardant used in this embodiment contains at least a modified cyclic phenoxy phosphazene compound represented by formula (I) below.

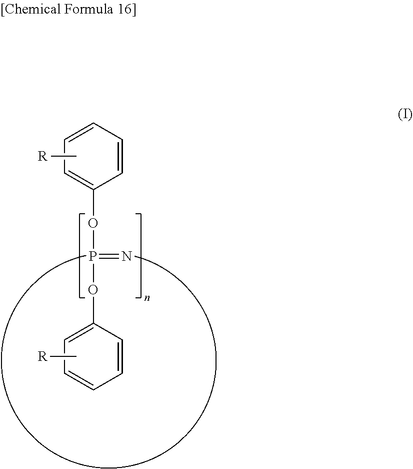

In the above-mentioned formula (I), n represents an integer from 3 to 25. At least one of R's represents a C1 to C10 aliphatic alkyl group or cyano group, and the remaining R's represent a hydrogen atom.

In general, cyclic phenoxy phosphazene compounds tend to be compatible with a resin component (a mixture of the component (A) and the component (B)). Thus, the use of such a modified cyclic phenoxy phosphazene compound as a flame retardant allows the resin composition according to this embodiment to have high flame retardancy. The modified cyclic phenoxy phosphazene compound has a hydrophobic molecular structure due to the presence of the modifying functional group and may accordingly be more compatible with a resin component (a mixture of the component (A) and the component (B)) than a typical cyclic phenoxy phosphazene compound.

Thus, the use of the modified cyclic phenoxy phosphazene compound in the resin composition according to this embodiment allows the resin composition to have high heat resistance and high resin flow compared with the use of a typical cyclic phenoxy phosphazene compound. An advantage of high resin flow is that high formability is imparted with a smaller amount of cyclic phenoxy phosphazene compound than conventional so that a decrease in Tg due to an increased amount of cyclic phenoxy phosphazene compound can be suppressed. Compared with a typical cyclic phenoxy phosphazene compound, the modified cyclic phenoxy phosphazene compound has a bulky molecular structure because of the presence of the modifying functional group, and the proportion of a phosphazene backbone per molecular volume is small. Thus, the use of the modified cyclic phenoxy phosphazene compound in the resin composition according to this embodiment allows the resin composition to exhibit low dielectric characteristics.

The aliphatic alkyl group is not limited and may be any C1 to C10 aliphatic alkyl group, and examples include a methyl group and an ethyl group. Among these groups, a methyl group is preferred.

The presence of such a modified cyclic phenoxy phosphazene compound enables the resin composition according to this embodiment to have high heat resistance and good low dielectric characteristics and also have both high formability and high Tg while the resin composition maintains high flame retardancy.

The flame retardant (C) according to this embodiment may further include an incompatible phosphorus compound in addition to the modified cyclic phenoxy phosphazene compound. The presence of an incompatible phosphorus compound may suppress decreases in Tg and heat resistance and provide a resin composition having high flame retardancy.

The incompatible phosphorus compound that can be used is not limited and may be any incompatible phosphorus compound that acts as a flame retardant and is incompatible with the mixture. The term “incompatible” as used herein refers to a state in which a target substance (phosphorus compound) is incompatible with a mixture of the modified polyphenylene ether compound (A) and the crosslinking curing agent (B) and is dispersed like islands in the mixture. The term “compatible” refers to a state in which a target substance is finely dispersed, fbr example, at a molecular level in a mixture of the modified polyphenylene ether compound (A) and the crosslinking curing agent (B).

Specific examples of the incompatible phosphorus compound include phosphinate compounds, phosphine oxide compounds, polyphosphate compounds, and phosphonium salt compounds. Examples of phosphinate compounds include aluminum dialkylphosphinate, aluminum trisdiethylphosphinate, aluminum trismethylethylphosphinate, aluminum trisdiphenylphosphinate, zinc bisdiethylphosphinate, zinc bismethylethylphosphinate, zinc bisdiphenylphosphinate, titanyl bisdiethylphosphinate, titanyl bismethylethylphosphinate, and titanyl bisdiphenylphosphinate. Examples of phosphine oxide compounds include xylylene bisdiphenylphosphine oxide, phenylene bisdiphenylphosphine oxide, biphenylene bisdiphenylphosphine oxide, and naphthylene bisdiphenylphosphine oxide. Examples of polyphosphate compounds include melamine polyphosphate, melam polyphosphate, and melem polyphosphate. Examples of phosphonium salt compounds include tetraphenylphosphonium tetraphenylborate, and tetraphenylphosphonium bromide. The incompatible phosphorus compound may be used alone or in combination of two or more.

The resin composition according to this embodiment may contain a flame retardant other than the forgoing flame retardants as a flame retardant, but preferably does not contain a halogenated flame retardant from a halogen-free viewpoint.

In the resin composition according to this embodiment, the amount of phosphorus atoms is preferably from 1.0 to 5.1 parts by mass per 100 parts by mass of the total of organic components (excluding the flame retardant) and the flame retardant.

The amount of the flame retardant (C) is preferably such that the amount of phosphorus atoms in the resin composition is in the above range. When the flame retardant (C) is present in such an amount, the resin composition provides a cured product with high heat resistance and flame retardancy while maintaining good dielectric characteristics attributed to the polyphenylene ether.

This may be because it is possible to sufficiently enhance flame retardancy while sufficiently suppressing deterioration of, for example, dielectric characteristics and heat resistance of a cured product due to the presence of the flame retardant. As used herein, organic components (excluding the flame retardant) refer to components including organic components, such as the modified polyphenylene ether compound and the crosslinking curing agent. In the case of additionally adding other organic components, organic components include these additionally added organic components.

In the case where the modified cyclic phenoxy phosphazene compound and the incompatible phosphorus compound are used in combination as the flame retardant (C), the content ratio of these compounds is preferably modified cyclic phenoxy phosphazene compound:incompatible phosphorus compound=90:10 to 10:90 in terms of mass ratio. When these compounds are present in such a content ratio, the resin composition provides a cured product with high flame retardancy while the resin composition maintains good dielectric characteristics attributed to the polyphenylene ether and good formability attributed to the modified cyclic phenoxy phosphazene.

The polyphenylene ether resin composition according to this embodiment may be composed of the modified polyphenylene ether compound (A), the thermosetting curing agent (B), and the flame retardant (C), but may further contain other components as long as the polyphenylene ether resin composition contains these components. Examples of other components include fillers, additives, and reaction initiators.

The resin composition according to this embodiment may further contain a filler as described above. Examples of the filler include, but are not limited to, substances added to enhance the heat resistance and flame retardancy of a cured product of the resin composition. The presence of the filler can further enhance, for example, heat resistance and flame retardancy. Specific examples of the filler include silica, such as spherical silica; metal oxides, such as alumina, titanium oxide, and mica; metal hydroxides, such as aluminum hydroxide and magnesium hydroxide; talc; aluminum borate; barium sulfate; and calcium carbonate. Among these, the filler is preferably silica, mica, or talc, more preferably spherical silica. The filler may be used alone or in combination of two or more.

The filler may be used without any treatment or may be used after being subjected to a surface treatment with an epoxysilane-type, vinylsilane-type, or aminosilane-type silane coupling agent. The silane coupling agent may be added by an integral blending method instead of a method of subjecting the filler to a surface treatment in advance.

When the resin composition according to this embodiment contains a filler, the amount of the filler is preferably from 10 to 200 parts by mass, more preferably from 30 to 150 parts by mass per 100 parts by mass of the total of organic components (excluding the flame retardant) and the flame retardant.

The resin composition according to this embodiment may further contain an additive as described above. Examples of the additive include antifoaming agents such as silicone-based antifoaming agents and acrylic acid ester-based antifoaming agents, heat stabilizers, antistatic agents, ultraviolet absorbers, dyes, pigments, lubricants, and dispersants such as wetting dispersants.

The polyphenylene ether resin composition according to this embodiment may further contain a reaction initiator as described above. Even if the polyphenylene ether resin composition is composed of a modified polyphenylene ether and a thermosetting curing agent, the curing reaction may proceed. Even if the polyphenylene ether resin composition is composed only of a modified polyphenylene ether, the curing reaction may proceed. However, depending on process conditions, it may be difficult to increase temperature until curing proceeds. Thus, a reaction initiator may be added. The reaction initiator is not limited and may be any reaction initiator that can accelerate the curing reaction between the modified polyphenylene ether and the thermosetting curing agent. Specific examples of the reaction initiator include oxidants, such as α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile. If necessary, a carboxylic acid metal salt or the like can be used in combination. This further accelerates the curing reaction. Among these, α,α′-bis(t-butylperoxy-m-isopropyl)benzene is preferably used. Since α,α′-bis(t-butylperoxy-m-isopropyl)benzene has a relatively high reaction initiation temperature, the curing reaction is unlikely to accelerate at the time during which it is not necessary to perform curing, such as during prepreg drying, and the polyphenylene ether resin composition can maintain its storage stability. Since α,α′-bis(t-butylperoxy-m-isopropyl)benzene further has low volatility, it does not volatilize during prepreg drying or storage and thus have high stability. The reaction initiator may be used alone or in combination of two or more.

Next, a prepreg, a metal-clad laminate, and a wiring board each obtained by using the polyphenylene ether resin composition according to this embodiment will be described with reference the drawings. The reference signs in the drawings are as follows: 1: prepreg, 2: resin composition or semi-cured product of resin composition, 3: fibrous base material, 11: metal-clad laminate, 12: insulating layer, 13: metal foil, 14: wiring, and 21: wiring board.

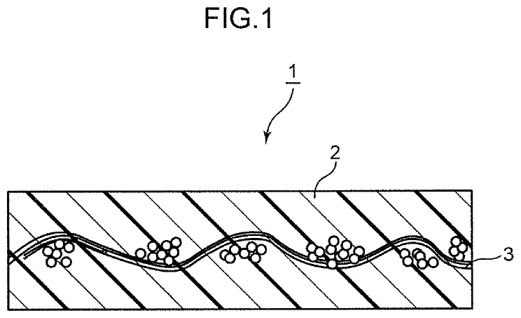

FIG. 1 is a schematic cross-sectional view illustrating an example of a prepreg 1 according to an embodiment of the present invention.

As illustrated FIG. 1, the prepreg 1 according to this embodiment includes a resin composition 2 or a semi-cured product 2 of the resin composition, and a fibrous base material 3. Examples of the prepreg 1 include a prepreg in which the fibrous base material 3 is present in the resin composition 2 or in the semi-cured product 2 of the resin composition. In other words, the prepreg 1 includes the resin composition or the semi-cured product of the resin composition, and the fibrous base material 3 present in the resin composition 2 or in the semi-cured product 2 of the resin composition.

In this embodiment, the term “semi-cured product” refers to a product formed by partially curing the resin composition to such an extent that the resin composition can be further cured. In other words, the semi-cured product refers to the resin composition in a semi-cured state (B stage). For example, when the resin composition is heated, the viscosity gradually decreases first, then curing starts, and the viscosity gradually increases. In this case, the semi-cured state refers to, for example, a state after the viscosity starts to increase and before the resin composition is completely cured.

The prepreg obtained by using the resin composition according to this embodiment may be a prepreg including a semi-cured product of the resin composition as described above or may be a prepreg including the resin composition which is not cured. In other words, the prepreg may be a prepreg including a semi-cured product (the resin composition in B stage) of the resin composition and a fibrous base material, or may be a prepreg including the resin composition before curing (the resin composition in A stage) and a fibrous base material. Specific examples of the prepreg include a prepreg in which a fibrous base material is present in the resin composition.

In manufacturing the prepreg 1, the polyphenylene ether resin composition according to this embodiment is often prepared in the form of varnish and used as a resin varnish. The resin varnish is prepared, for example, in the following manner.

First, organic solvent-soluble components, such as a modified polyphenylene ether compound, a crosslinking curing agent, and a modified cyclic phenoxy phosphazene compound, are placed in an organic solvent and dissolved in it. In this case, heating may be performed as necessary. Thereafter, components that are used as necessary and insoluble in an organic solvent, such as an inorganic filler and an incompatible flame retardant, are added to the organic solvent and dispersed in a ball mill, a bead mill, a planetary mixer, a roll mill, or the like until a predetermined dispersion state is obtained, whereby a varnish-like composition is prepared. The organic solvent used here is not limited and may be any organic solvent in which a modified polyphenylene ether compound, a crosslinking curing agent, a flame retardant, and the like are soluble and that does not inhibit the curing reaction. Specific examples of the organic solvent include toluene and methyl ethyl ketone (MEK).

Examples of the method for manufacturing the prepreg 1 according to this embodiment by using the obtained resin varnish include a method involving impregnating the fibrous base material 3 with the resin composition 2 prepared in the form of the obtained resin varnish and drying the fibrous base material 3.

Specific examples of the fibrous base material used to manufacture the prepreg 1 include glass cloth, aramid cloth, polyester cloth, LCP (liquid crystal polymer) non-woven fabric, glass non-woven fabric, aramid non-woven fabric, polyester non-woven fabric, pulp paper, and linter paper. The use of glass cloth provides a laminate having high mechanical strength, and flattened glass cloth is particularly preferred. Specifically, flattening processing can be performed by, for example, continuously pressing glass cloth with a press roll at an appropriate pressure so as to flatten yarns. The fibrous base material having a thickness of, for example, from 0.02 to 0.3 mm can be commonly used.

The impregnation of the fibrous base material 3 with the resin varnish (resin composition) is performed by dipping, coating, or the like. This impregnation can be repeated several times as necessary. In this case, the finally desired composition (content ratio) and resin amount can be controlled by repeating impregnation using plural resin varnishes having different compositions and concentrations.

The fibrous base material 3 impregnated with the resin composition 2 is heated under desired heating conditions, for example, 80° C. or higher and 180° C. or lower for 1 minute or longer and 10 minutes or shorter. The solvent is evaporated from the varnish by heating to provide the prepreg 1 before curing (A stage) or in a semi-cured state (B stage).

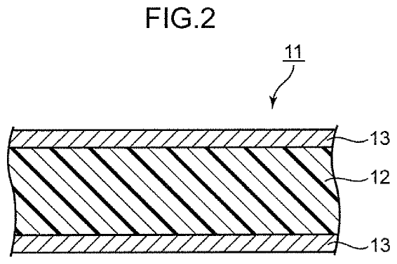

As illustrated in FIG. 2, a metal-clad laminate 11 according to this embodiment includes an insulating layer 12 containing a cured product of the resin composition or a cured product of the prepreg, and a metal foil 13.

An example method of preparing the metal-clad laminate 11 by using the prepreg 1 produced as described above involves: stacking one or more prepregs 1 on top of one another, further stacking a metal foil 13, such as copper foil, on the upper and lower surfaces or one surface of each of the prepregs 1; and integrating the metal foils 13 and the prepregs 1 by hot-press forming to prepare a double-sided metal clad laminate or a single-sided metal clad laminate. That is, the metal-clad laminate 11 according to this embodiment of the present invention is produced by stacking the metal foil 13 on the prepreg 1 and performing hot-press forming. The hot-press conditions can be appropriately set according to the thickness of a laminate to be manufactured, the type of resin composition of the prepreg, and the like. For example, the temperature may be from 170° C. to 210° C., and the pressure may be from 1.5 to 4.0 MPa, and the time may be from 60 to 150 minutes.

The metal-clad laminate 11 according to this embodiment may be produced by forming a film-like resin composition on the metal foil 13 without using the prepreg 1 or the like and then performing hot pressing.

The polyphenylene ether resin composition according to this embodiment provides a cured product with high heat resistance and flame retardancy while maintaining good dielectric characteristics attributed to the polyphenylene ether. The polyphenylene ether resin composition according to this embodiment further has high resin flow and thus has good formability. Therefore, the prepreg obtained by using this resin composition enables manufacture of a metal-clad laminate having good dielectric characteristics and high heat resistance and flame retardancy. The metal-clad laminate obtained by using the prepreg enables manufacture of a wiring board having good dielectric characteristics, high Tg, and high heat resistance and flame retardancy.

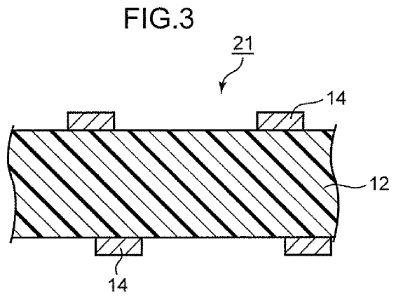

As illustrated in FIG. 3, a wiring board 21 according to this embodiment includes an insulating layer 12 containing a cured product of the resin composition or a cured product of the prepreg, and wiring 14.

An example method for manufacturing the wiring board 21 involves, for example, forming a circuit (wiring) by etching the metal foil 13 on the surface of the metal-clad laminate 13 produced as described above to provide the wiring board 21 having a conductive pattern (wiring 14), serving as a circuit, on the surface of the laminate. The wiring board 21 has good dielectric characteristics, high Tg, and high heat resistance and flame retardancy. Examples of the circuit forming method include, in addition to the above method, circuit formation through a semi-additive process (SAP) and a modified semi additive process (MSAP).

The present specification discloses techniques according to various aspects as described above, and the main techniques among them are summarized below.

A polyphenylene ether resin composition according to an aspect of the present invention includes (A) a modified polyphenylene ether compound having a terminal modified with a substituent having an unsaturated carbon-carbon double bond, (B) a crosslinking curing agent having an unsaturated carbon-carbon double bond in the molecule, and (C) a flame retardant. The flame retardant (C) contains at least a modified cyclic phenoxy phosphazene compound represented by formula (I) below.

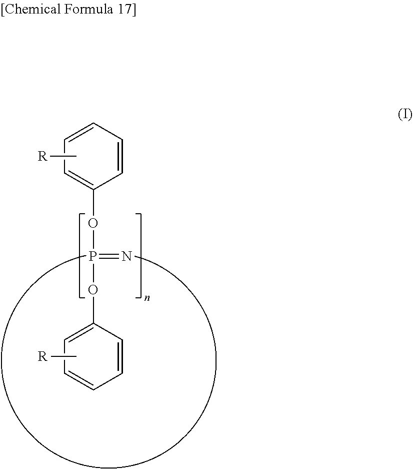

In the above-mentioned formula (I), n represents an integer from 3 to 25. At least one of R's represents a C1 to C10 aliphatic alkyl group or cyano group, and the remaining R's represent a hydrogen atom.

This configuration can provide a resin composition having good dielectric characteristics and high flame retardancy and heat resistance and also having high formability and high Tg.

In the modified cyclic phenoxy phosphazene compound in the polyphenylene ether resin composition, at least one of R's in formula (I) preferably has a C1 to C10 aliphatic alkyl group. This may provide the above effects more assuredly.

In the polyphenylene ether resin composition, the flame retardant (C) preferably further contains an incompatible phosphorus compound that is incompatible with a mixture of the modified polyphenylene ether compound (A) and the crosslinking curing agent (B). The presence of the incompatible phosphorus compound advantageously suppresses decreases in Tg and heat resistance and provides a resin composition having high flame retardancy.

When the polyphenylene ether resin composition contains the incompatible phosphorus compound, the content ratio of the modified cyclic phenoxy phosphazene compound to the incompatible phosphorus compound is preferably from 90:10 to 10:90 in terms of mass ratio. This allows the resin composition to provide a cured product with high flame retardancy while the resin composition maintains high formability.

The incompatible phosphorus compound is preferably at least one selected from the group consisting of phosphinate compounds, phosphine oxide compounds, polyphosphate compounds, and phosphonium salt compounds. This provides the above effects more assuredly.

In the polyphenylene ether resin composition, the amount of phosphorus atoms is preferably from 1.0 to 5.1 parts by mass per 100 parts by mass of the total of organic components (excluding the flame retardant (C)) and the flame retardant (C). This provides the above effects more assuredly.

The substituent in the terminal of the modified polyphenylene ether compound is preferably a substituent having at least one selected from the group consisting of a vinylbenzyl group, an acrylate group, and a methacrylate group.

The prepreg according to another aspect of the present invention has the polyphenylene ether resin composition or a semi-cured product of the resin composition.

The metal-clad laminate according to yet another aspect of the present invention includes an insulating layer containing a cured product of the polyphenylene ether resin composition or a cured product of the prepreg, and a metal foil.

The wiring board according to yet another aspect of the present invention includes an insulating layer containing a cured product of the polyphenylene ether resin composition or a cured product of the prepreg, and wiring.

The prepreg, metal-clad laminate, and wiring board according to the present invention have good dielectric characteristics, good formability, high Tg, and high heat resistance and flame retardancy and are thus very useful in industrial applications.

The present invention will be more specifically described below by way of Examples, but the scope of the present invention is not limited to these.

### EXAMPLES

First, components used to prepare a resin composition in Examples will be described.

<Component A: Polyphenylene Ether>

—Modified PPE-1: Bifunctional Vinylbenzyl Modified PPE (Mw: 1900)

First, modified polyphenylene ether (modified PPE-1) was synthesized. The average number of phenolic hydroxyl groups in the molecule terminal per polyphenylene ether molecule is referred to as the number of terminal hydroxyl groups.

A polyphenylene ether was caused to react with chloromethylstyrene to produce a modified polyphenylene ether 1 (modified PPE-1). Specifically, first, 200 g of polyphenylene ether (SA 90 available from SABIC Innovative Plastics, intrinsic viscosity (IV): 0.083 dl/g, the number of terminal hydroxyl groups: 1.9, weight molecular weight Mw: 1700), 30 g of a mixture (CMS: chloromethylstyrene available from Tokyo Chemical Industry Co., Ltd.) of p-chloromethylstyrene and m-chloromethylstyrene in a mass ratio of 50:50, 1.227 g of tetra-n-butylammonium bromide, serving as a phase-transfer catalyst, and 400 g of toluene were placed in a 1-liter three-necked flask equipped with a temperature controller, a stirrer, a cooling system, and a dropping funnel, and the mixture was stirred. Then, the mixture was stirred until the polyphenylene ether, chloromethylstyrene, and tetra-n-butylammonium bromide were dissolved in toluene. During stirring, the solution was gradually heated until the solution temperature finally reached 75° C. An aqueous solution of sodium hydroxide (20 g sodium hydroxide/20 g water), serving as an alkali metal hydroxide, was then added dropwise to the solution over 20 minutes. Then, the mixture was further stirred at 75° C. for 4 hours. Next, the contents of the flask were neutralized with 10 mass % hydrochloric acid, and then a large amount of methanol was then added to the flask. This process formed a precipitate in the liquid in the flask. In other words, the product contained in the reaction solution in the flask was reprecipitated. The precipitate was then removed by filtration, washed 3 times with a mixture of methanol and water in a mass ratio of 80:20, and then dried at 80° C. for 3 hours under reduced pressure.

The obtained solid was analyzed with ¹H-NMR (400 MHz, CDCl3, TMS). As a result of NMR analysis, a peak from ethenylbenzyl was found at 5 to 7 ppm. This result indicates that the obtained solid was a modified polyphenylene ether having the group represented by formula (1) in the molecule terminal. Specifically, the obtained solid was confirmed to be ethenylbenzylated polyphenylene ether.

The molecular weight distribution of the modified polyphenylene ether was measured by using GPC. The weight-average molecular weight (Mw) was calculated from the obtained molecular weight distribution and, as a result, found to be 1900.

The number of terminal functional groups in the modified polyphenylene ether was measured in the following manner.

First, the modified polyphenylene ether was weighed accurately. The weight at this time was taken as X (mg). The weighed modified polyphenylene ether was dissolved in 25 mL of methylene chloride. To the solution was added 100 μL of a 10 mass % solution of tetraethylammonium hydroxide (TEAH) in ethanol (TEAH:ethanol (volume ratio)=15:85). The absorbance (Abs) of the solution at 318 nm was then measured by using a UV spectrophotometer (UV-1600 available from Shimadzu Corporation). From the measurement result, the number of terminal hydroxyl groups in the modified polyphenylene ether was calculated by using the following formula.

Amount of Residual OH (μmol/g)−[(25×Abs)/(ε×OPL×X)]×106

In the formula, ε represents an absorption coefficient of 4700 L/mol·cm. OPL represents an optical path length of 1 cm.

The calculated amount of residual OH (the number of terminal hydroxyl groups) in the modified polyphenylene ether was substantially zero, which indicates that most of hydroxyl groups in the polyphenylene ether before modification were modified. This result shows that the decrement from the number of terminal hydroxyl groups in the polyphenylene ether before modification corresponds to the number of terminal hydroxyl groups in the polyphenylene ether before modification. In other words, the number of terminal hydroxyl groups in the polyphenylene ether before modification is found to correspond to the number of terminal functional groups in the modified polyphenylene ether. Specifically, the number of terminal functional groups was 1.8.
SA-9000: bifunctional methacrylate modified PPE (Mw: 1700, available from SABIC Innovative Plastics)

<Component B: Crosslinking Curing Agent>
DCP: dicyclopentediene methacrylate (DCP methacrylate available from Shin-Nakamura Chemical Co., Ltd., weight-average molecular weight Mw: 332, the number of terminal double bonds: 2)
DVB: divinylbenzene (DVB810 available from Nippon Steel & Sumitomo Metal Corporation, molecular weight: 130, the number of terminal double bonds: 2)
Polybutadiene oligomer: polybutadiene oligomer (B-1000 available from Nippon Soda Co., Ltd., weight-average molecular weight Mw: 1100, the number of terminal double bonds: 15)

<Component C: Flame Retardant>

(Modified Cyclic Phenoxy Phosphazene Compound)
“SPB-100L” (available from Otsuka Chemical Co., Ltd., methyl group-modified cyclic phosphazene; phosphorus concentration: 12.6 mass %)
“FP-300B” (available from FUSHIMI Pharmaceutical Co., Ltd., cyano group-modified cyclic phosphazene; phosphorus concentration: 11.6 mass %) (Other Cyclic Phosphazene Compounds)
“SPB-100” (available from Otsuka Chemical Co., Ltd., cyclic phosphazene compound; phosphorus concentration: 13.0 mass %) (Incompatible Phosphorus Compound)
“Exolit OP-935” (available from Clariant Japan K.K., phosphinate compound: aluminum tris(diethylphosphinate); phosphorus concentration: 23 mass %)
“PQ60” (available from Chin Yee Chemical Industries Ltd., phosphine oxide compound, xylylenebis(diphenylphosphine oxide); phosphorus concentration: 12.0%)

(Reaction Initiator)
PERHEXYNE (registered trademark) 25B (Nippon Oil & Fats Co., Ltd., peroxide)

### Examples 1 to 14, Comparative Examples 1 to 6

### [Preparation Method] (Resin Varnish)

First, components were added to toluene in the mixture ratio shown in Tables 1 and 2 so as to obtain a solid content of 60 mass %, followed by mixing. The mixture was stirred for 60 minutes to provide a varnish-like resin composition (varnish).

(Prepreg I)

A glass cloth (#1067 type available from Asahi Kasei Corporation, E-glass) was impregnated with a resin varnish according to Examples and Comparative Examples and then dried by heating at 100° C. to 170° C. for about 3 to 6 minutes to provide a prepreg. In this case, the prepreg was prepared so as to have a resin composition content (resin content) of about 74 mass % relative to the weight of the prepreg.

(Prepreg II)

A glass cloth (#2116 type available from Asahi Kasei Corporation, E-glass) was impregnated with a resin varnish in Examples and Comparative Examples and then dried by heating at 100° C. to 170° C. for about 3 to 6 minutes to provide a prepreg. In this case, the prepreg was prepared so as to have a resin composition content (resin content) of about 45 mass % relative to the weight of the prepreg.

<Evaluation Test>

(Resin Flow)

The resin flow of the prepreg 1 obtained by using the resin varnish according to Examples and Comparative Examples was measured in accordance with IPC-TM-650. The prepreg was subjected to hot-plate pressing for 15 minutes under the forming conditions of a temperature of 170° C. and a pressure of 14.1 kgf/cm². Regarding the number of prepregs used for measurement, four prepregs 1 produced as described above were used.

(Circuit Filling Properties—Lattice Pattern (Residual Copper Rate) 70%)

A 35-μm-thick copper foil (“GTHMP35” available from Furukawa Electric Co., Ltd.) was disposed on each side of the prepreg II to prepare a workpiece. The workpiece was hot-pressed under the conditions of a temperature of 200° C. and a pressure of 40 kg/cm² for 120 minutes to provide a 0.1-mm-thick copper-clad laminate in which a copper foil was bonded to each surface.

A lattice pattern was formed on the copper foil on each surface of the copper-clad laminate such that the residual copper rate on each surface was 70%, thus forming a circuit. One prepreg 1 was stacked on each surface of the board having this circuit, and a 12-μm-thick copper foil (“GTHMP12” available from Furukawa Electric Co., Ltd.) was disposed thereon to prepare a workpiece. The workpiece was hot-pressed under the same conditions as those in manufacture of the copper-clad laminate. The entire surface of the outer layer copper foil was then etched to provide a sample. The formed laminate (laminate for evaluation) in which a sufficient amount of the prepreg-derived resin composition was placed between the circuits and no void was formed between the circuits was rated “o”. A formed laminate in which a sufficient amount of the prepreg-derived resin composition was not placed between the circuits and voids were formed between the circuits was rated “x”. Voids can be visually observed.

(Circuit Filling Properties—Lattice Pattern (Residual Copper Rate) 50%)

The presence of voids was checked by the same method as for the evaluation of circuit filling properties except that the pattern was formed such that the residual copper rate was 50%.

(Circuit Filling Properties—Lattice Pattern (Residual Copper Rate) 30%)

The presence of voids was checked by the same method as for the evaluation of circuit filling properties except that the pattern was formed such that the residual copper rate was 30%.

(Dielectric Characteristics: Dissipation Factor (Df)

Twelve prepregs 1 were stacked on top of one another and subjected to hot-plate pressing for 120 minutes under the forming conditions of a temperature of 200° C. and a pressure of 40 kgf/cm².

The dissipation factor (Df) of the obtained sample was measured by the cavity resonator perturbation method. Specifically, the dissipation factor of the test board at 10 GHz was measured by using a network analyzer (N5230A available from Agilent Technologies).

(Glass Transition Temperature (Tg))

A 12-μm-thick copper foil (“GTHMP12” available from Furukawa Electric Co., Ltd) was disposed on each side of one prepreg 1 to prepare a workpiece. The workpiece was hot-pressed under the conditions of a temperature of 200° C. and a pressure of 40 kg/cm² for 120 minutes to provide a 0.06-mm-thick copper-clad laminate in which a copper foil was bonded to each surface. The entire surface of the outer layer copper foil was then etched to provide a sample.

The Tg of the obtained sample was measured by using a viscoelastic spectrometer “DMS 100” available from Seiko Instruments Inc. At this time, dynamic mechanical analysis (DMA) was performed at a frequency of 10 Hz by using a tensile module, and the temperature at which tan 6 reached a maximum in heating from room temperature to 280° C. at a heating rate of 5° C./min was defined as Tg.

(Flame Retardancy)

Four prepregs II were stacked on top of one another and hot-pressed at a temperature of 200° C. and a pressure of 40 kg/cm² for 120 minutes to provide a sample having a thickness of about 0.4 mm.

A test piece having a length of 125 mm and a width of 12.5 mm was cut out from the sample. The test piece was subjected to a flammability test 10 times in accordance with Underwriters Laboratories “Test for Flammability of Plastic Materials-UL 94”. Specifically, five test pieces were subjected to the flammability test 2 times for each test piece. The flame retardancy was evaluated on the basis of the total flaming combustion time in the flammability test.

(Heat Resistance)

The heat resistance was evaluated in accordance with the JIS C 6481 standard. A sample was produced as follows: a 12-μm-thick copper foil (“GTHMP12” available from Furukawa Electric Co., Ltd) was disposed on each side of one prepreg 1 to prepare a workpiece, and the workpiece was hot-pressed under the conditions of a temperature of 200° C. and a pressure of 40 kg/cm² for 120 minutes to provide a 0.06-mm-thick copper-clad laminate in which a copper foil was bonded to each surface. The copper-clad laminate was cut into a predetermined size and left to stand in thermostatic baths at 280° C. and 290° C. for one hour, and the copper-clad laminate that had been cut into a predetermined size was then left to stand in a thermostatic bath at a predetermined temperature for one hour and then taken out of the thermostatic bath. The heated test pieces were visually observed. A test piece in which no blistering occurred at 290° C. was rated ⊙. A test piece in which blistering occurred at 290° C. and no blistering occurred at 280° C. was rated ∘. A test piece in which blistering occurred at 280° C. was rated x.

The above results are shown in Tables 1 and 2.

TABLE 1

| | | | | | Ex- | Ex- | Ex- | Ex- | Ex- | Ex- | Ex- |
|---|---|---|---|---|---|---|---|---|---|---|---|
| | | | | P- | am- | am- | am- | am- | am- | am- | am- |
| | | | | Con- | ple | ple | ple | ple | ple | ple | ple |
| Resin | | | | tent | 1 | 2 | 3 | 4 | 5 | 6 | 7 |
| Modified PPE | | Vinyl- | Modified | | 75 | 75 | 75 | 75 | 75 | 75 | 75 |
| | | Modified | PPE-1 | | | | | | | | |
| | | Methacrylate- | SA9000 | | | | | | | | |
| | | Modified | | | | | | | | | |
| Crosslinking | | DCP | DCP | | 25 | 25 | 25 | 25 | 25 | 25 | 25 |
| Curing | | DVB | DVB810 | | | | | | | | |
| Agent | | Polybutadiene | B-1000 | | | | | | | | |
| Flame | Modified | Methyl Group- | SPB-100L | 12.6% | 25 | 15 | 10 | 5 | 2 | 2 | |
| Retar- | Cyclic | Modified | | | | | | | | | |
| dant | Phenoxy | Cyclic | | | | | | | | | |
| | Phosphazene | Phosphazene | | | | | | | | | |
| | Compound | Cyano Group- | FP-300B | 11.6% | | | | | | | 25 |
| | | Modified | | | | | | | | | |
| | | Cyclic | | | | | | | | | |
| | | Phosphazene | | | | | | | | | |
| | | Cyclic | SPB-100 | 13.0% | | | | | | | |
| | | Phosphazene | | | | | | | | | |
| | Incompatible | Phosphinate | OP935 | 23% | | | | 10 | 10 | | |
| | Phosphorus | Compound | | | | | | | | | |
| | Compound | Phosphine | PQ60 | 12% | | | | | | 13 | |
| | | Oxide | | | | | | | | | |
| | | Compound | | | | | | | | | |

| | | | | | | | | |
|---|---|---|---|---|---|---|---|---|
| Phosphorus | | 2.5% | 1.6% | 1.1% | 2.5% | 2.3% | 1.6% | 2.3% |
| Concentration | | | | | | | | |
| Characteristics | Resin Flow | 42% | 35% | 31% | 20% | 17% | 25% | 35% |
| | Circuit Filling | ∘ | ∘ | ∘ | ∘ | ∘ | ∘ | ∘ |
| | Properties | | | | | | | |
| | (Lattice 70%) | | | | | | | |
| | Circuit Filling | ∘ | ∘ | ∘ | ∘ | ∘ | ∘ | ∘ |
| | Properties | | | | | | | |
| | (Lattice 50%) | | | | | | | |
| | Circuit Filling | ∘ | ∘ | ∘ | ∘ | ∘ | ∘ | ∘ |
| | Properties | | | | | | | |
| | (Lattice 30%) | | | | | | | |
| | Flame | 35 | 41 | 46 | 19 | 24 | 35 | 37 |
| | Resistance | | | | | | | |
| | (sec) | | | | | | | |
| | Df | 0.0050 | 0.0050 | 0.0050 | 0.0040 | 0.0040 | 0.0040 | 0.0050 |
| | Tg (° C.) | 180 | 200 | 210 | 220 | 225 | 225 | 180 |
| | Heat | | | | | | | |
| | Resistance | ∘ | ⊙ | ⊙ | ⊙ | ⊙ | ⊙ | ⊙ |

| | | | | Ex- | Ex- | Ex- | Ex- | Ex- | Ex- | Ex- |
|---|---|---|---|---|---|---|---|---|---|---|
| | | | | am- | am- | am- | am- | am- | am- | am- |
| | | | | ple | ple | ple | ple | ple | ple | ple |
| Resin | | | | 8 | 9 | 10 | 11 | 12 | 13 | 14 |
| Modified PPE | | Vinyl- | Modified | 75 | 75 | 75 | 75 | 75 | 75 | 75 |
| | | Modified | PPE-1 | | | | | | | |
| | | Methacrylate- | SA9000 | | | | | | | |
| | | Modified | | | | | | | | |
| Crosslinking | | DCP | DCP | 25 | 25 | 25 | 25 | 25 | | |
| Curing | | DVB | DVB810 | | | | | | 25 | |
| Agent | | Polybutadiene | B-1000 | | | | | | | 25 |
| Flame | Modified | Methyl Group- | SPB-100L | | | | | | 25 | 25 |
| Retar- | Cyclic | Modified | | | | | | | | |
| dant | Phenoxy | Cyclic | | | | | | | | |
| | Phosphazene | Phosphazene | | | | | | | | |
| | Compound | Cyano Group- | FP-300B | 15 | 10 | 5 | 2 | 2 | | |
| | | Modified | | | | | | | | |
| | | Cyclic | | | | | | | | |
| | | Phosphazene | | | | | | | | |
| | | Cyclic | SPB-100 | | | | | | | |
| | | Phosphazene | | | | | | | | |
| | Incompatible | Phosphinate | OP935 | | | 10 | 10 | | | |
| | Phosphorus | Compound | | | | | | | | |
| | Compound | Phosphine | PQ60 | | | | | 13 | | |
| | | Oxide | | | | | | | | |
| | | Compound | | | | | | | | |

| | | | | | | | | |
|---|---|---|---|---|---|---|---|---|
| Phosphorus | | 1.5% | 1.1% | 2.5% | 2.3% | 1.6% | 2.5% | 2.5% |
| Concentration | | | | | | | | |
| Characteristics | Resin Flow | 32% | 25% | 16% | 12% | 20% | 43% | 40% |
| | Circuit Filling | ∘ | ∘ | ∘ | ∘ | ∘ | ∘ | ∘ |
| | Properties | | | | | | | |
| | (Lattice 70%) | | | | | | | |
| | Circuit Filling | ∘ | ∘ | ∘ | ∘ | ∘ | ∘ | ∘ |
| | Properties | | | | | | | |
| | (Lattice 50%) | | | | | | | |
| | Circuit Filling | ∘ | ∘ | ∘ | ∘ | ∘ | ∘ | ∘ |
| | Properties | | | | | | | |
| | (Lattice 30%) | | | | | | | |
| | Flame | 43 | 50 | 21 | 26 | 37 | 36 | 36 |
| | Resistance | | | | | | | |
| | (sec) | | | | | | | |
| | Df | 0.0050 | 0.0050 | 0.0040 | 0.0040 | 0.0040 | 0.0050 | 0.0050 |
| | Tg (° C.) | 200 | 210 | 220 | 225 | 225 | 180 | 180 |
| | Heat | | | | | | | |
| | Resistance | ⊙ | ⊙ | ⊙ | ⊙ | ⊙ | ∘ | ∘ |

TABLE 2

| | | | | P- | Comparative | Comparative | Comparative | Comparative | Comparative | Comparative |
|---|---|---|---|---|---|---|---|---|---|---|
| | | | | Con- | Example | Example | Example | Example | Example | Example |
| Resin | | | | tent | 1 | 2 | 3 | 4 | 5 | 6 |
| Modified PPE | | Vinyl- | Modified | | 75 | 75 | 75 | 75 | 75 | 75 |
| | | Modified | PPE-1 | | | | | | | |
| | | Methacrylate- | SA9000 | | | | | | | |
| | | Modified | | | | | | | | |
| Crosslinking | | DCP | DCP | | 25 | 25 | 25 | 25 | | |
| Curing | | DVB | DVB810 | | | | | | 25 | |
| Agent | | Polybutadiene | B-1000 | | | | | | | 25 |
| Flame | Modified | Methyl Group- | SPB-100L | 12.6% | | | | | | |
| Retar- | Cyclic | Modified | | | | | | | | |
| dant | Phenoxy | Cyclic | | | | | | | | |
| | Phosphazene | Phosphazene | | | | | | | | |
| | Compound | Cyano Group- | FP-300B | 11.6% | | | | | | |
| | | Modified | | | | | | | | |
| | | Cyclic | | | | | | | | |
| | | Phosphazene | | | | | | | | |
| | | Cyclic | SPB-100 | 13.0% | 25 | 15 | 10 | | 25 | 25 |
| | | Phosphazene | | | | | | | | |
| | Incompatible | Phosphinate | OP935 | 23% | | | | 12 | | |
| | Phosphorus | Compound | | | | | | | | |
| | Compound | Phosphine | PQ60 | 12% | | | | | | |
| | | Oxide | | | | | | | | |
| | | Compound | | | | | | | | |

| | | | | | | | |
|---|---|---|---|---|---|---|---|
| Phosphorus | | 2.6% | 1.7% | 1.2% | 2.5% | 2.6% | 2.6% |
| Concentration | | | | | | | |
| Characteristics | Resin Flow | 42% | 35% | 31% | 20% | I 7% | 25% |
| | Circuit Filling | ∘ | ∘ | ∘ | × | ∘ | ∘ |
| | Properties | | | | | | |
| | (Lattice 70%) | | | | | | |
| | Circuit Filling | ∘ | ∘ | ∘ | × | ∘ | ∘ |
| | Properties | | | | | | |
| | (Lattice 50%) | | | | | | |
| | Circuit Filling | ∘ | ∘ | ∘ | × | ∘ | ∘ |
| | Properties | | | | | | |
| | (Lattice 30%) | | | | | | |
| | Flame | 35 | 41 | 48 | 94 | 36 | 36 |
| | Resistance | | | | | | |
| | (sec) | | | | | | |
| | Df | 0.0060 | 0.0060 | 0.0060 | 0.0050 | 0.0060 | 0.0060 |
| | Tg (° C.) | 180 | 200 | 210 | 230 | 180 | 180 |
| | Heat | | | | | | |
| | Resistance | × | ∘ | ⊙ | ⊙ | × | × |

(Discussion)

The results shown in Tables 1 and 2 indicate that the present invention can provide a resin composition having good dielectric characteristics and high flame retardancy and heat resistance and also having good formability and high Tg.

In the present invention, the resin composition has high resin flow although containing a relatively small amount of modified cyclic phosphazene compound. It is thus shown that high formability and high Tg are obtained with a small amount of the modified cyclic phosphazene compound.

It is also found that, when the resin composition further contains an incompatible phosphorus compound as a flame retardant, in addition to the modified cyclic phenoxy phosphazene compound according to the present invention, the resin composition has high Tg while containing a smaller amount of highly compatible modified cyclic phenoxy phosphazene compound (e.g., see Examples 4 to 6 and 10 to 12).

However, it is found that the resin compositions in Comparative Examples 1 to 3 and 5 to 6 containing, as a flame retardant, a cyclic phosphazene compound instead of the modified cyclic phenoxy phosphazene compound according to the present invention have high Df at 10 GHz. It is further revealed that the use of a conventional cyclic phosphazene compound degrades resin flow and formability. It is also shown that, if the amount of a conventional cyclic phosphazene compound is increased in order to obtain sufficient formability, the resin composition has low heat resistance and low Tg and thus has high Df. In Comparative Example 4 where only an incompatible phosphorus compound is used as a flame retardant, the resin flow is low, which degrades circuit filling properties.

### Examples 15 to 16, Comparative Examples 7 to 8

The resin varnishes according to Examples 15 to 16 and Comparative Examples 7 to 8 were produced in the same manner as in Example 1 except that the mixture ratio of the components was changed to that described in Table 3.

The obtained resin varnishes were used to produce samples, such as prepregs and metal-clad laminates similar to those in Example 1, and subjected to the same evaluation test as that in Example 1. The results are shown in Table 3.

TABLE 3

| | | | | | Ex- | Ex- | | |
|---|---|---|---|---|---|---|---|---|
| | | | | P- | am- | am- | Comparative | Comparative |
| | | | | Con- | ple | ple | Example | Example |
| Resin | | | | tent | 15 | 16 | 7 | 8 |
| Modified PPE | | Vinyl- | Modified | | | | | |
| | | Modified | PPE-1 | | | | | |
| | | Methacrylate- | SA9000 | | 75 | 75 | 75 | 75 |
| | | Modified | | | | | | |
| Crosslinking | | DCP | DCP | | 25 | 25 | 25 | 25 |
| Curing | | | | | | | | |
| Agent | | | | | | | | |
| Flame | Modified | Methyl Group- | SPB-100L | 12.6% | 25 | 2 | | |
| Retar- | Cyclic | Modified | | | | | | |
| dant | Phenoxy | Cyclic | | | | | | |
| | Phosphazene | Phosphazene | | | | | | |
| | Compound | Cyano Group- | FP-300B | 11.6% | | | | |
| | | Modified | | | | | | |
| | | Cyclic | | | | | | |
| | | Phosphazene | | | | | | |
| | | Cyclic | SPB-100 | 13.0% | | | 25 | 2 |
| | | Phosphazene | | | | | | |
| | Incompatible | Phosphinate | OP935 | 23% | | 10 | | 10 |
| | Phosphorus | Compound | | | | | | |
| | Compound | Phosphine | PQ60 | 12% | | | | |
| | | Oxide | | | | | | |
| | | Compound | | | | | | |

| | | | | | | |
|---|---|---|---|---|---|---|
| Reaction Initiator | Peroxide | PERHEXYNE 25 B | 0.5 | 0.5 | 0.5 | 0.5 |
| Phosphorus | | | 2.5% | 2.3% | 2.6% | 2.3% |
| Concentration | | | | | | |
| Characteristics | | Resin Flow | 23% | 8% | 10% | 5% |
| | | Circuit Filling | ∘ | ∘ | ∘ | × |
| | | Properties | | | | |
| | | (Lattice 70%) | | | | |
| | | Flame | 35 | 26 | 35 | 26 |
| | | Resistance | | | | |
| | | (sec) | | | | |
| | | Df | 0.0055 | 0.0045 | 0.0065 | 0.0055 |
| | | Tg (° C.) | 200 | 240 | 200 | 240 |
| | | Heat | | | | |
| | | Resistance | ∘ | ⊙ | × | ⊙ |

(Discussion)

The results shown in Table 3 indicate that, even in the case of using a modified polyphenylene ether that is different from that in Examples 1 to 14, resin compositions having better dielectric characteristics and higher flame retardancy and heat resistance and also having better formability and higher Tg than the resin compositions in Comparative Examples 7 to 8 containing the modified polyphenylene ether, a crosslinking curing agent, and a conventional flame retardant (cyclic phosphazene compound) can be provided.

This application is based on Japanese Patent Application No. 2017-166462 filed Aug. 31, 2017, the entire contents of which are incorporated herein by reference.

To express the present invention, the present invention is appropriately and sufficiently described above by way of the embodiments with reference to specific examples and the like. However, it should be recognized that those skilled in the art can easily modify and/or improve the embodiments. Therefore, it is to be understood that the modifications or improvements carried out by those skilled in the art fall within the scope of the claims unless the modifications or improvements depart from the scope of the claims recited in the appended claims.

### INDUSTRIAL APPLICABILITY

The present invention has a wide range of industrial applicability in technical fields related to electronic materials and various devices including such electronic materials.

1. A polyphenylene ether resin composition comprising:
(A) a modified polyphenylene ether compound having a terminal modified with a substituent having an unsaturated carbon-carbon double bond;
(B) a crosslinking curing agent having an unsaturated carbon-carbon double bond in a molecule; and
(C) a flame retardant,
wherein the flame retardant (C) contains at least a modified cyclic phenoxy phosphazene compound represented by formula (I) below: 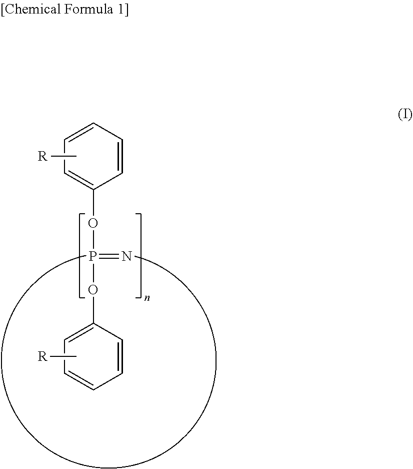
(wherein n represents an integer from 3 to 25, and at least two of R's represent a C1 to C10 aliphatic alkyl group, and the remaining R's represent a hydrogen atom).

2. The polyphenylene ether resin composition according to claim 1, wherein, in the modified cyclic phenoxy phosphazene compound, at least one of R's in formula (I) has a C1 to C10 aliphatic alkyl group.

3. The polyphenylene ether resin composition according to claim 1, wherein the flame retardant (C) further contains an incompatible phosphorus compound that is incompatible with a mixture of the modified polyphenylene ether compound (A) and the crosslinking curing agent (B).

4. The polyphenylene ether resin composition according to claim 3, wherein a content ratio of the modified cyclic phenoxy phosphazene compound to the incompatible phosphorus compound is from 90:10 to 10:90 in terms of mass ratio.

5. The polyphenylene ether resin composition according to claim 3, wherein the incompatible phosphorus compound comprises at least one selected from the group consisting of phosphinate compounds, phosphine oxide compounds, polyphosphate compounds, and phosphonium salt compounds.

6. The polyphenylene ether resin composition according to claim 1, wherein an amount of phosphorus atoms in the polyphenylene ether resin composition is from 1.0 to 5.1 parts by mass per 100 parts by mass of a total of organic components (excluding the flame retardant (C)) and the flame retardant (C).

7. The polyphenylene ether resin composition according to claim 1, wherein the substituent in a terminal of the modified polyphenylene ether compound comprises a substituent having at least one selected from the group consisting of a vinylbenzyl group, an acrylate group, and a methacrylate group.

8. A prepreg comprising a fibrous base material and the resin composition according to claim 1 or a semi-cured product of the resin composition.

9. A metal-clad laminate comprising a metal foil and an insulating layer containing a cured product of the resin composition according to claim 1.

10. A wiring board comprising wiring and an insulating layer containing a cured product of the resin composition according to claim 1.

11. A metal-clad laminate comprising a metal foil and an insulating layer containing a cured product of the prepreg according to claim 8.

12. A wiring board comprising wiring and an insulating layer containing a cured product of the prepreg according to claim 8.
